(19) United States
(12) Patent Application Publication
(10) Pub. No.: US 2024/0038743 A1
(43) Pub. Date: Feb. 1, 2024

(54) SMALLER MODULE BY STACKING

(71) Applicant: Avago Technologies International Sales Pte. Limited, Singapore (SG)

(72) Inventors: Dingyou Zhang, San Jose, CA (US); Li Sun, San Jose, CA (US)

(21) Appl. No.: 17/875,647

(22) Filed: Jul. 28, 2022

(51) Int. Cl. H01L 25/16; H05K 1/18; H01L 21/56; H01L 23/498; H01L 23/00; H01L 23/31

(52) U.S. Cl. CPC H01L 25/162; H05K 1/183; H05K 1/181; H01L 21/563; H01L 23/49833; H01L 24/16; H01L 24/48; H01L 24/32; H01L 24/73; H01L 24/13; H01L 23/3135; H05K 2201/10015; H05K 2201/1003; H01L 2924/15321; H01L 2924/3025; H01L 2924/2027; H01L 2924/182; H01L 2224/13147; H01L 2224/13155; H01L 2924/19042; H01L 2924/19041; H01L 2224/16227; H01L 2224/16238; H01L 2224/48229; H01L 2224/32145; H01L 2224/32227; H01L 2224/32238; H01L 2224/16148; H01L 2224/13005; H01L 2224/73265; H01L 2224/73253; H01L 2224/73215

(57) ABSTRACT

A module is described. The module includes two dies which are stacked over a top insulating layer of a PCB. When both dies are be connected to the PCB through a copper pillar, the top die has a taller interconnect and the bottom die has a shorter interconnect. To further reduce a height of the module, the bottom die and/or the top die may be placed into a cavity of the PCB and a bulk silicon layer of the top die may be grinded away.

### TECHNICAL FIELD

The present invention generally relates to methods, systems and apparatuses for integrated circuit (IC) packages including a substrate having interconnection layers.

### BACKGROUND

There is steady demand for the solid-state modules inside electronic products, such as cellular telephones, personal communication devices and portable computers, to be physically smaller. Limiting factors that affect the size and height of such a solid-state module include printed circuit boards (PCBs) and various components mounted to either or both sides of the PCBs, incorporated in the module package.

Module size reduction in the x and y directions (e.g., where x and y directions correspond to a width and a length of a module) is a driving factor in module design. The dies and passive components are mounted on a PCB top surface next to each other, resulting in a module with a given size (in x and y). The placement of the dies and passive components on the PCB top surface may thus become a bottleneck for reducing the overall module size reduction (in x and y directions).

For example, flip-chip dies, filters, and surface mount technology (SMT) components may be connected to a top surface of a PCB, in which case the height of the tallest SMT component must be accommodated by the overall height of the module containing the PCB. High Q inductors, in particular, tend to be taller than other electronic components mounted to a PCB, creating a barrier against overall module height reduction (in a z direction, where z corresponds to a height of a module).

In view of the above, one or more embodiments of the present disclosure provide a module with die stacking to reduce a size in the x and y directions, and to reduce the module height in the z direction at the same time.

### SUMMARY

A module is disclosed, in accordance with one or more illustrative embodiments. In some embodiments, the module includes a printed circuit board (PCB) including a plurality of metal layers. In some embodiments, a first metal layer of the plurality of metal layers is disposed on a top insulating layer of the PCB. In some embodiments, the module includes a first die electrically and/or mechanically coupled to the PCB by a first flip-chip mounting. In some embodiments, the PCB defines a cavity with a second metal layer of the plurality of metal layers disposed on a bottom surface of the cavity. In some embodiments, the module includes a second die electrically and/or mechanically coupled to the bottom surface of the PCB cavity by a second flip-chip mounting. In some embodiments, at least a portion of the second die is disposed between the first die and the PCB such that the first die is stacked over the second die. In some embodiments, the first die is separated from the second die by a gap. In some embodiments, a height of the first flip-chip mounting is taller than a height of the second flip-chip mounting. In some embodiments, at least two opposing ends of the first die extend beyond the second die.

In some embodiments, the first flip-chip mounting mechanically supports the at least two opposing ends of the first die. In some embodiments, the module can may include one or more component electrically coupled to the first metal layer. In some embodiments, the module includes a molding compound formed over the component, the second die, and the top insulating layer of the PCB.

In some embodiments, the first die may be flip-chip mounted to the second metal layer of the plurality of metal layers at the bottom surface of the cavity. In some embodiments, the cavity may be formed through one or more intermediary metal layers, to further increase the depth of the cavity thus reducing the standoff height of the die stack above the PCB surface. In some embodiments, the flip-chip mounting may include solder bumps and/or copper pillars on the surface of the cavity and/or the top insulating layer of the PCB.

In some embodiments, the first die and the second die may be flip-chip mounted to the first metal layer on the top insulating layer of the PCB.

In some embodiments, the module may include an interposer. The interposer may be coupled between the top insulating layer of the PCB and one or more of the first die and the second die. Both the first die and the second die may be flip-chip mounted to the interposer. In some embodiments, the module may include a second molding compound. The second molding compound may enclose the flip-chip mounting of the second die. In some embodiments, the second molding compound includes conductive vias through all or a portion for the flip-chip mounting of the first die. In some embodiments, the second molding compound encloses the second die.

In some embodiments, the molding compound is over the first die. In some embodiments, the molding compound is around the first die, such that a top surface of the first die is exposed. A top surface of the SMT component may be disposed below the first die when the molding compound is not over the top surface of the first die. The top surface of the first die may be exposed by grinding the molding compound thereby reducing the height of the module. In some embodiments, the interposer may be coupled between the bottom surface of the PCB cavity and both of the first die and the second die.

In some embodiments, the flip-chip mounting of the first die includes copper pillars. In some embodiments, the flip-chip mounting of the second die includes nickel bumps. The copper pillars may be taller than the nickel bumps.

In some embodiments, the module includes a third die in addition to the first die and the second die. Similar to the second die, the third die may be disposed between the first die and the PCB.

In some embodiments, the second die includes a bank of silicon capacitors or an integrated passive device.

In some embodiments, the PCB includes a bottom insulating layer disposed opposite to the top insulating layer. The module may include ball grid array (BGA) balls coupled to the bottom surface.

A module is disclosed, in accordance with one or more illustrative embodiments. In some embodiments, the module includes a printed circuit board (PCB) including a plurality of metal layers. In some embodiments, the PCB defines a cavity. In some embodiments, a first metal layer of the plurality of metal layers is disposed on a top insulating layer of the PCB. In some embodiments, the module includes a first die electrically coupled to the first layer of the PCB by a first wire-bond. In some embodiments, the module includes a second die electrically and/or mechanically coupled to the bottom surface of a PCB cavity by a flip-chip mounting. In some embodiments, at least a portion of the second die is disposed between the first die and the PCB such that the first die is stacked over the second die. In some embodiments, the backside of the first die is attached to the backside of the second die by a first die attach film. In some embodiments, the first die is mechanically supported by the die attach film. In some embodiments, the module may include one or more components electrically coupled to the first metal layer. In some embodiments, the module includes a molding compound formed over the component, the second die, and the top insulating layer of the PCB.

In some embodiments, the second die is electrically coupled to the first metal layer by a wire-bond. The second die may be attached to the bottom surface of a PCB cavity by a second die attach film which mechanically supports the second die. The backside of the first die may then be attached to the face of the second die by the first die attach film. At least one end of the second die may extend beyond the first die for forming the second wire-bond.

A module is disclosed, in accordance with one or more illustrative embodiments. In some embodiments, the module includes a printed circuit board (PCB) including a plurality of metal layers. In some embodiments, a first metal layer of the plurality of metal layers is disposed on a top insulating layer of the PCB. In some embodiments, the module includes a first die electrically coupled to the PCB by a first flip-chip mounting between the first die and the first metal layer. In some embodiments, the module includes a second die electrically coupled to the first die by a second flip-chip mounting between a face of the second die and a face of the first die. In some embodiments, at least a portion of the second die is disposed between the first die and the PCB such that the first die is stacked over the second die. In some embodiments, a height of the first flip-chip mounting is taller than a height of the second flip-chip mounting. In some embodiments, the module may include one or more component electrically coupled to the first metal layer. In some embodiments, the module includes a molding compound formed over the component, the second die, and the top surface of the PCB.

In some embodiments, the molding compound is over the first die. In some embodiments, the molding compound is around the first die. A top surface of the SMT component may be disposed below a top surface of the first die. The top surface of the first die may then be exposed such that the molding compound is not over the top surface of the first die for reducing a height of the module. The top surface of the first die may be exposed by grinding the molding compound. In some embodiments, the first die may be flip-chip mounted to the bottom surface of the PCB cavity.

### BRIEF DESCRIPTION OF THE DRAWINGS

Implementations of the concepts disclosed herein may be better understood when consideration is given to the following detailed description thereof. Such description makes reference to the included drawings, which are not necessarily to scale, and in which some features may be exaggerated and some features may be omitted or may be represented schematically in the interest of clarity. Like reference numerals in the drawings may represent and refer to the same or similar element, feature, or function. In the drawings:

FIG. 1A depicts a side view of flip-chip dies stacking with one die placed inside a substrate cavity, in accordance with one or more embodiments of the present disclosure.

FIG. 1B depicts a side view of flip-chip dies stacking with both dies placed inside a substrate cavity, in accordance with one or more embodiments of the present disclosure.

FIG. 1C depicts a side view of flip-chip dies stacking withing a cavity substrate with a top die exposed, in accordance with one or more embodiments of the present disclosure.

FIG. 1D depicts a side view of flip-chip die and wire bond die stacking in a substrate cavity, in accordance with one or more embodiments of the present disclosure.

FIG. 1E depicts a side view of wire bond dies stacking in a substrate cavity, in accordance with one or more embodiments of the present disclosure.

FIG. 1F depicts a side view of flip-chip dies stacking on a PCB top surface, in accordance with one or more embodiments of the present disclosure.

FIG. 1G depicts a side view of flip-chip dies stacking on a PCB top surface with a top die exposed, in accordance with one or more embodiments of the present disclosure.

FIG. 1H depicts a side view of flip-chip dies stacking in a face-to-face configuration, in accordance with one or more embodiments of the present disclosure.

FIG. 1I depicts a side view of flip-chip dies stacking in a face-to-face configuration with a top die exposed, in accordance with one or more embodiments of the present disclosure.

FIG. 1J depicts a side view of flip-chip dies stacking in a face-to-face configuration inside a cavity, in accordance with one or more embodiments of the present disclosure.

FIG. 1K depicts a side view of flip-chip dies stacking on an interposer, in accordance with one or more embodiments of the present disclosure.

FIG. 1L depicts a side view of die stacking on an interposer with a top die exposed, in accordance with one or more embodiments of the present disclosure.

FIG. 1M depicts a side view of die stacking on an interposer inside a cavity, in accordance with one or more embodiments of the present disclosure.

FIG. 1N depicts a side view of die stacking on an interposer with two molding compounds on top of the top die, in accordance with one or more embodiments of the present disclosure.

FIGS. 2A-2L depict a top view of stacking overlay configurations, in accordance with one or more embodiments of the present disclosure.

### DETAILED DESCRIPTION OF THE INVENTION

Before explaining one or more embodiments of the disclosure in detail, it is to be understood that the embodiments are not limited in their application to the details of construction and the arrangement of the components or steps or methodologies set forth in the following description or illustrated in the drawings. In the following detailed description of embodiments, numerous specific details are set forth in order to provide a more thorough understanding of the disclosure. However, it will be apparent to one of ordinary skill in the art having the benefit of the instant disclosure that the embodiments disclosed herein may be practiced without some of these specific details. In other instances, well-known features may not be described in detail to avoid unnecessarily complicating the instant disclosure.

As used herein a letter following a reference numeral is intended to reference an embodiment of the feature or element that may be similar, but not necessarily identical, to a previously described element or feature bearing the same reference numeral (e.g., 1, 1a, 1b). Such shorthand notations are used for purposes of convenience only and should not be construed to limit the disclosure in any way unless expressly stated to the contrary.

Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

In addition, use of “a” or “an” may be employed to describe elements and components of embodiments disclosed herein. This is done merely for convenience and “a” and “an” are intended to include “one” or “at least one,” and the singular also includes the plural unless it is obvious that it is meant otherwise.

Finally, as used herein any reference to “one embodiment” or “some embodiments” means that a particular element, feature, structure, or characteristic described in connection with the embodiment is included in at least one embodiment disclosed herein. The appearances of the phrase “in some embodiments” in various places in the specification are not necessarily all referring to the same embodiment, and embodiments may include one or more of the features expressly described or inherently present herein, or any combination or sub-combination of two or more such features, along with any other features which may not necessarily be expressly described or inherently present in the instant disclosure.

It is noted herein “coupled” may mean one or more of communicatively coupled, electrically coupled, and/or physically coupled for the purposes of the present disclosure. As used herein, coupled may refer to a direct or indirect coupling. An indirect coupling may refer to a connection via another function element. A direct coupling may refer to a connection without intermediary functional elements. It is noted herein that by being “coupled between”, it may be understood to be relative to movement or flow of a signal between two or more components, and may additionally include intervening components therein. An electrical coupling or electrical connection may refer to the ability of electrical energy to flow between components. The terms electrical coupling and electrical connection may be used interchangeably. A mechanical coupling or mechanical attachment may refer to a physical support of components. The terms mechanical coupling and mechanical attachment may be used interchangeably. In some instances, the mechanical attachment is provided to support the component while a molding compound is formed over, around, and/or under the component. Once the molding compound is set, the molding compound in combination with the mechanical attachment may provide a desired level of a rigidity to the component.

Reference will now be made in detail to the subject matter disclosed, which is illustrated in the accompanying drawings. Embodiments of the present disclosure are generally directed to stacking dies or other components on the top surface of the PCB for floorplan optimization. A smaller package size in the x and y directions may be achieved by stacking the dies. The stacked dies may also be placed into a cavity of the PCB to further reduce the package height. As used herein, stacking may refer to placing a die above another die relative to a printed circuit board.

U.S. Pat. No. 10,827,617, titled “Printed circuit board with cavity”, naming Dingyou Zhang, Nitesh Kumbhat, Li Sun, Sarah Haney, and Chang Kyu Choi as inventors, is incorporated herein by reference in the entirety.

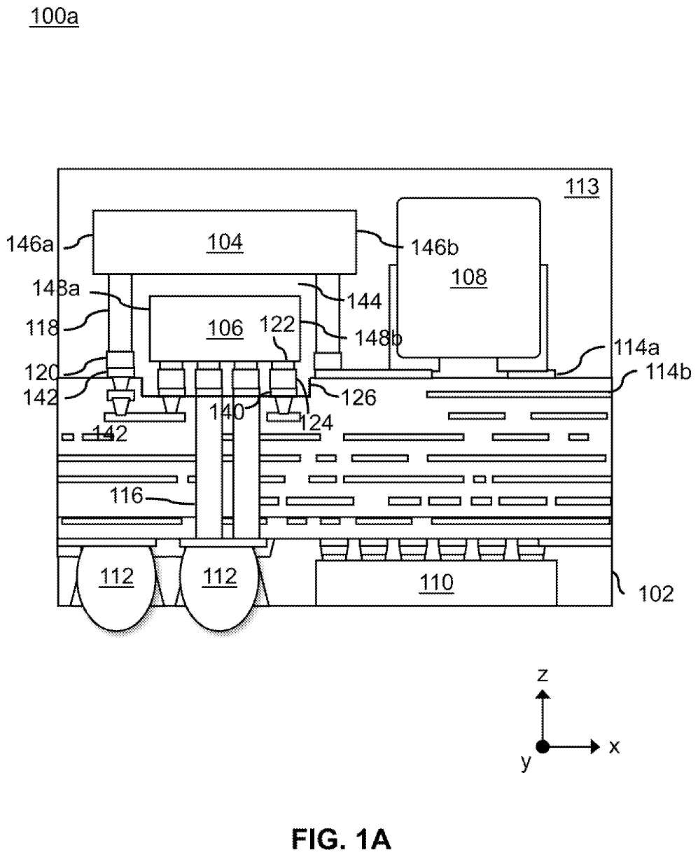

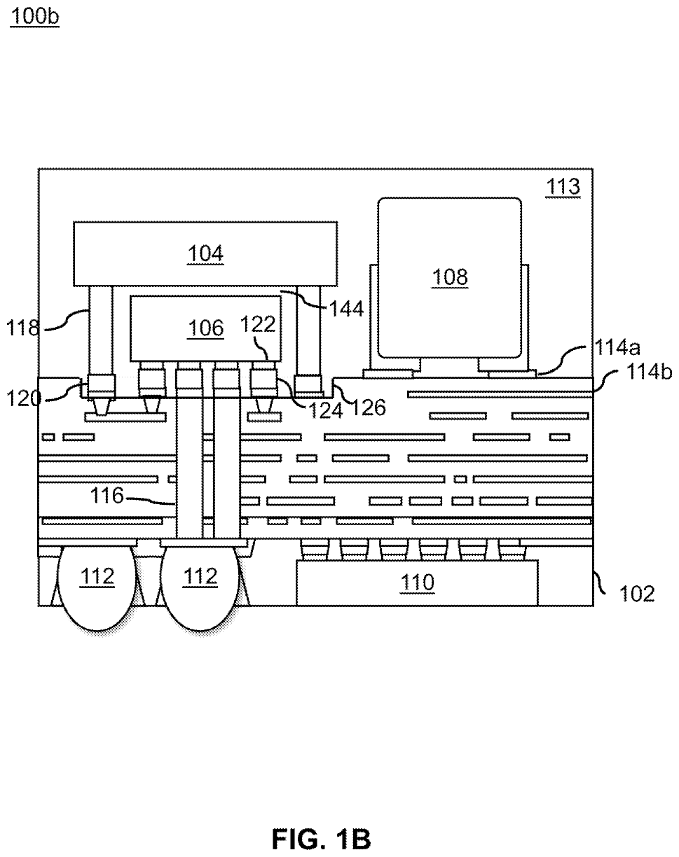

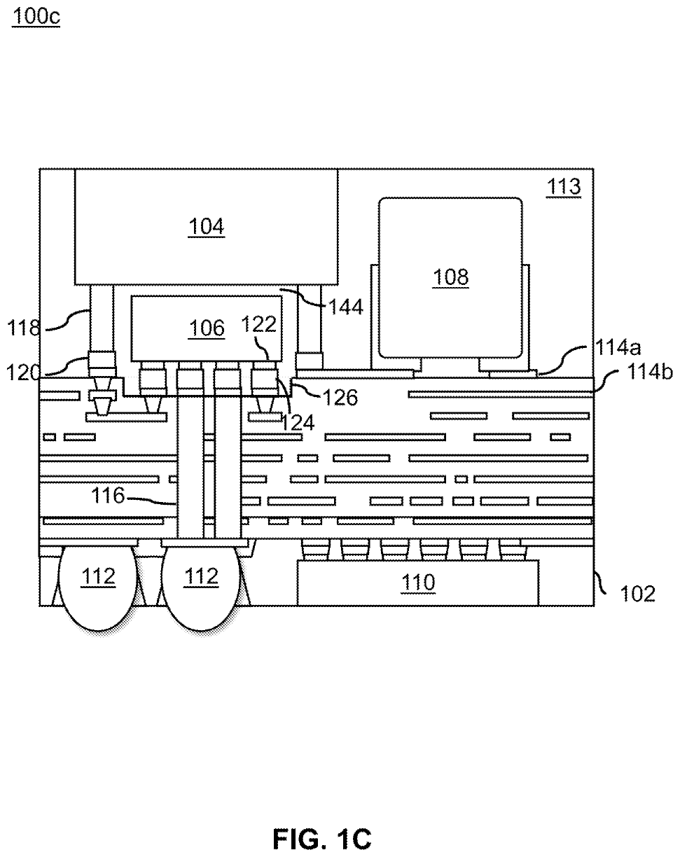

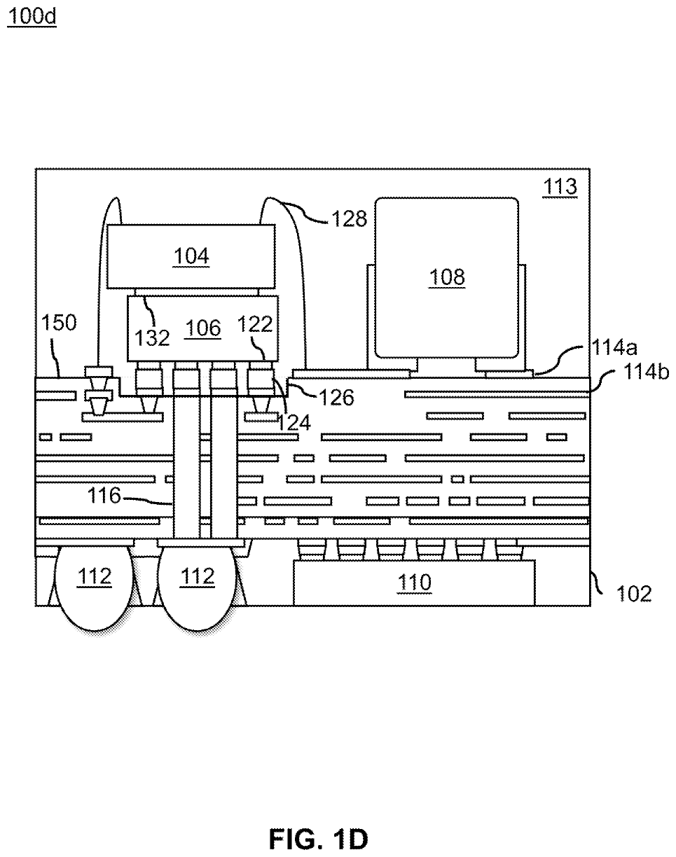

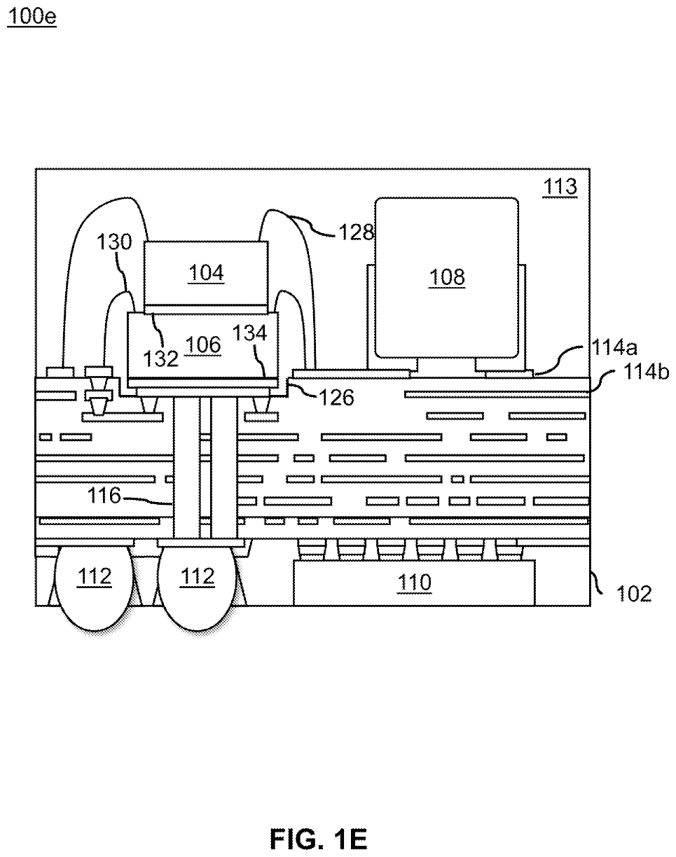

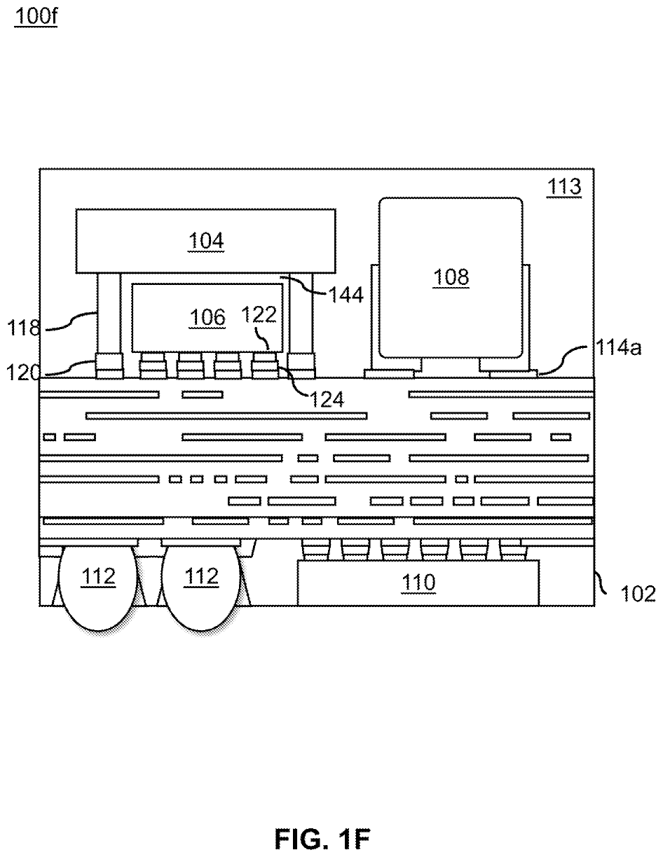

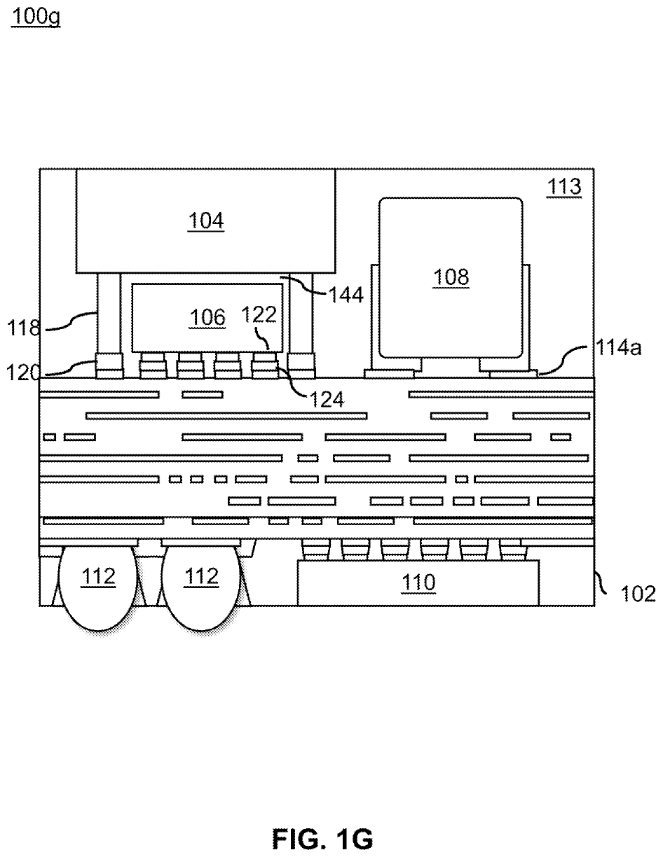

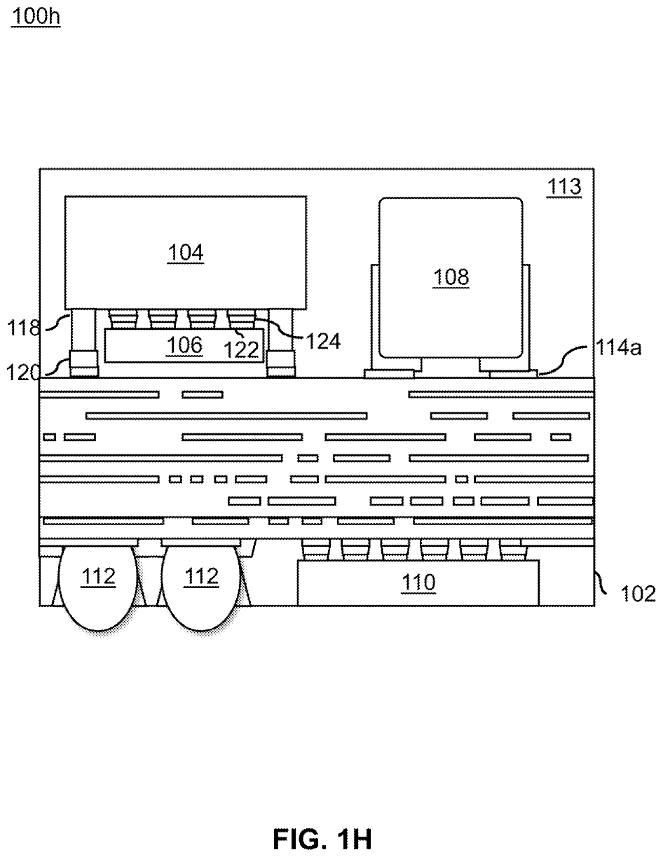

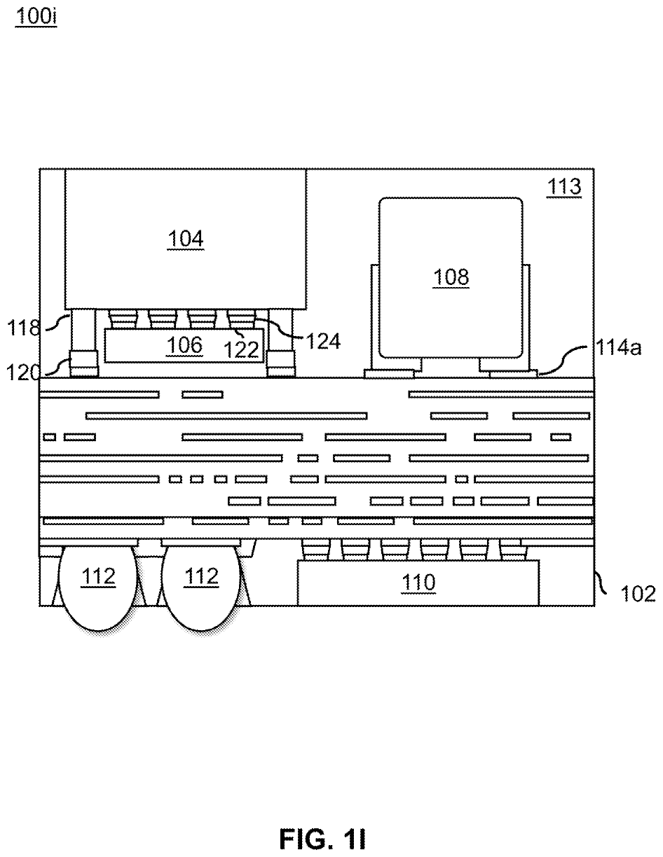

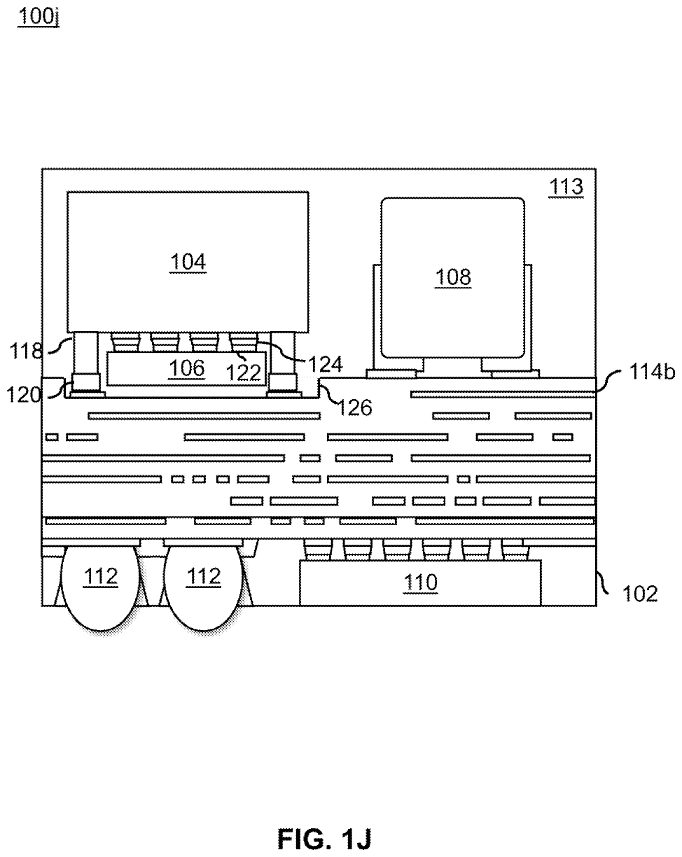

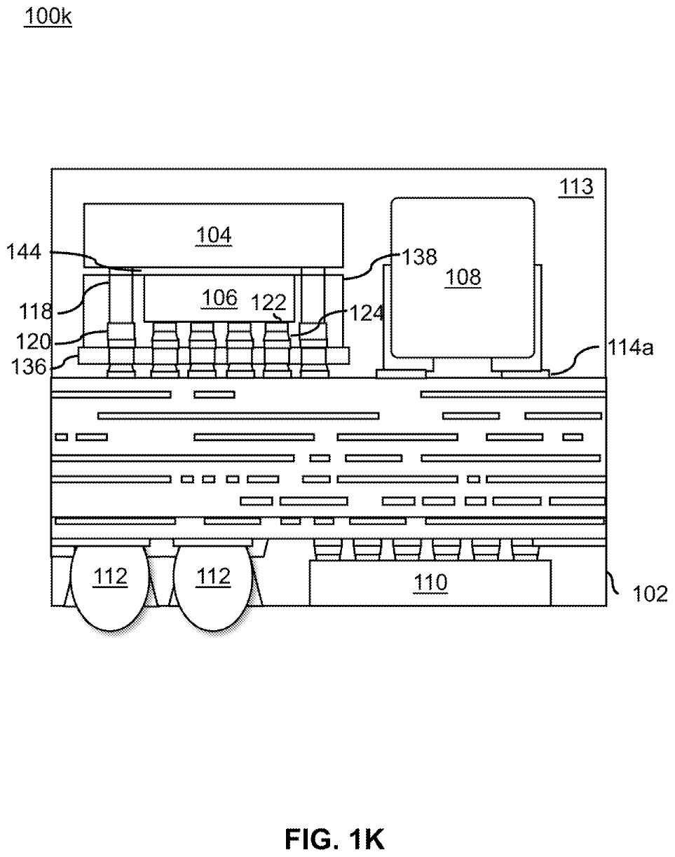

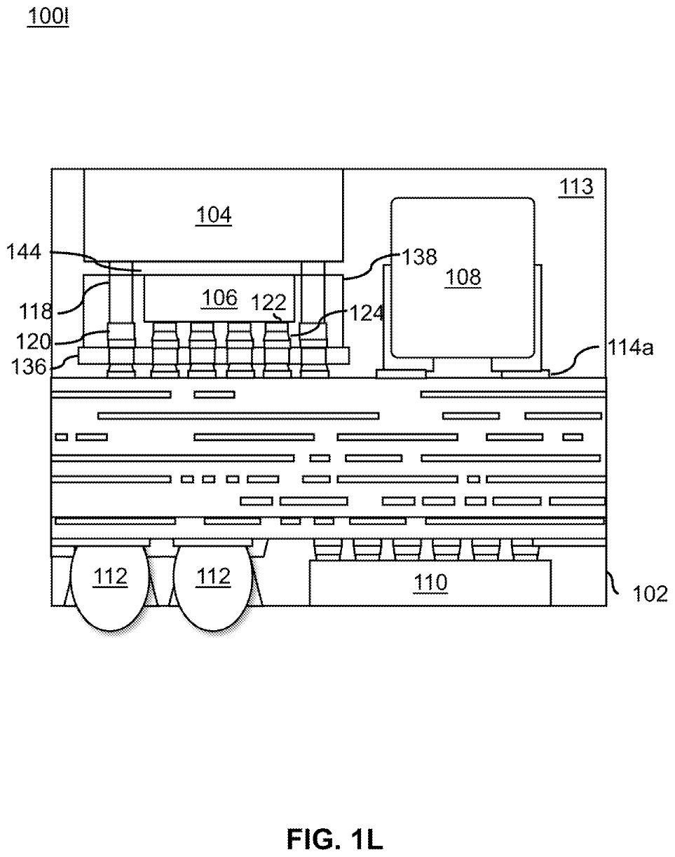

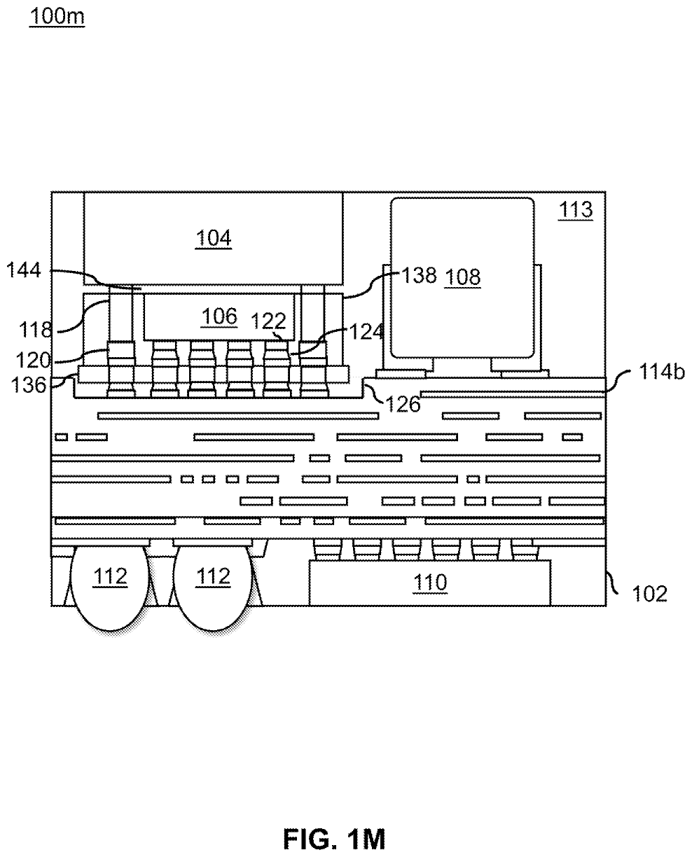

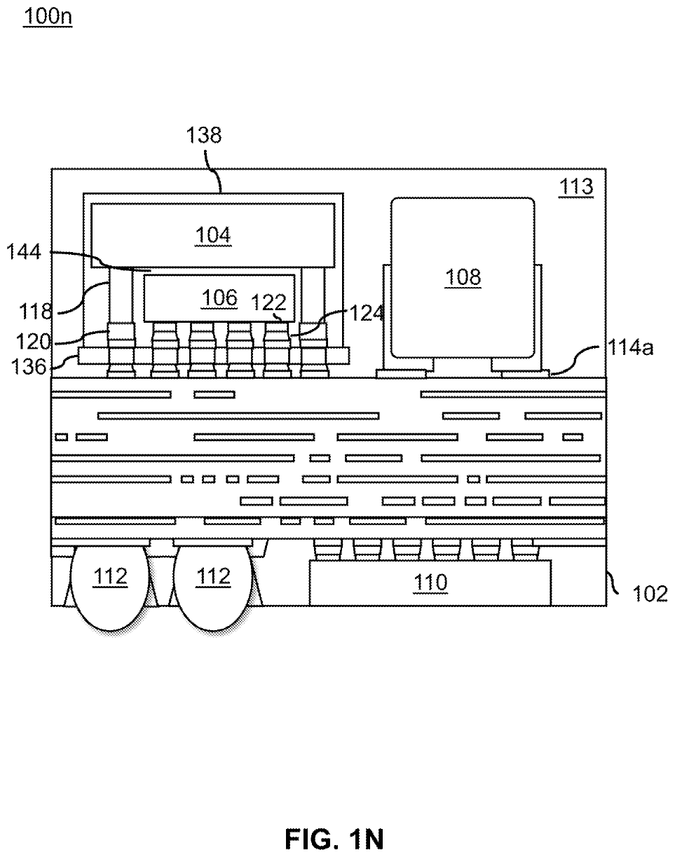

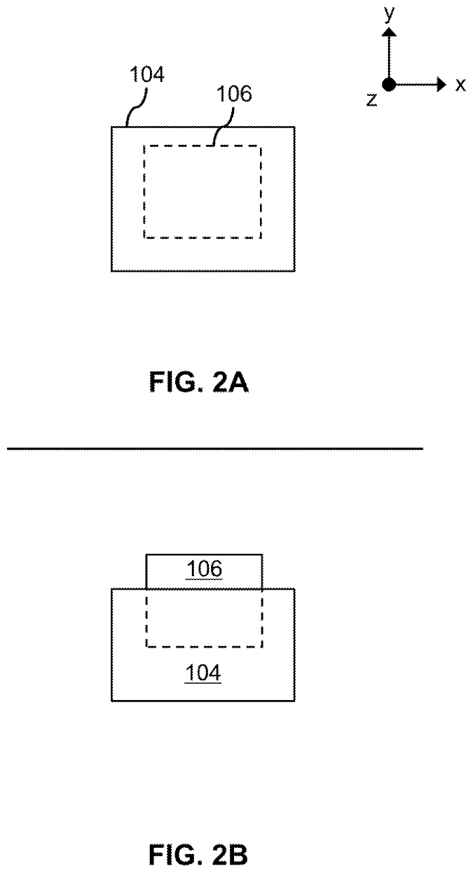

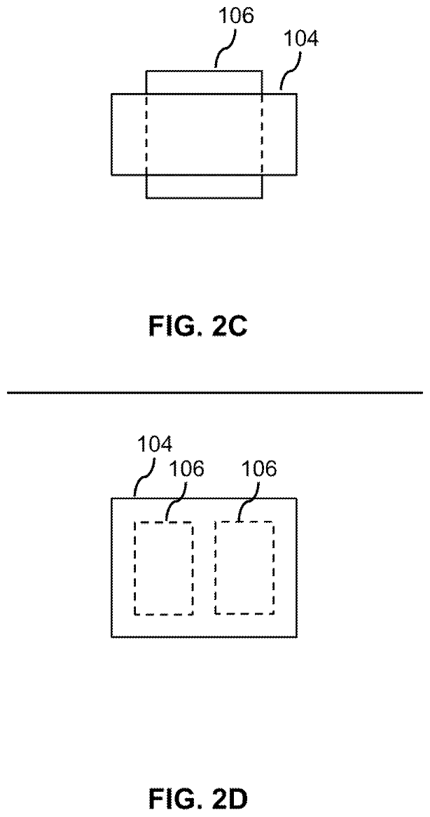

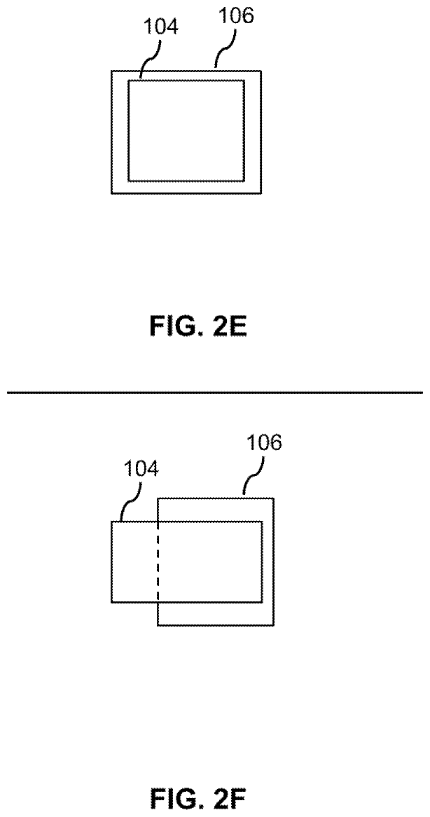

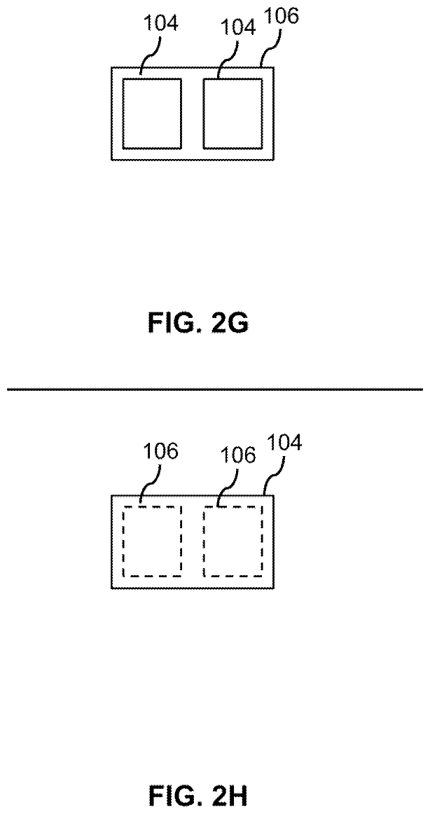

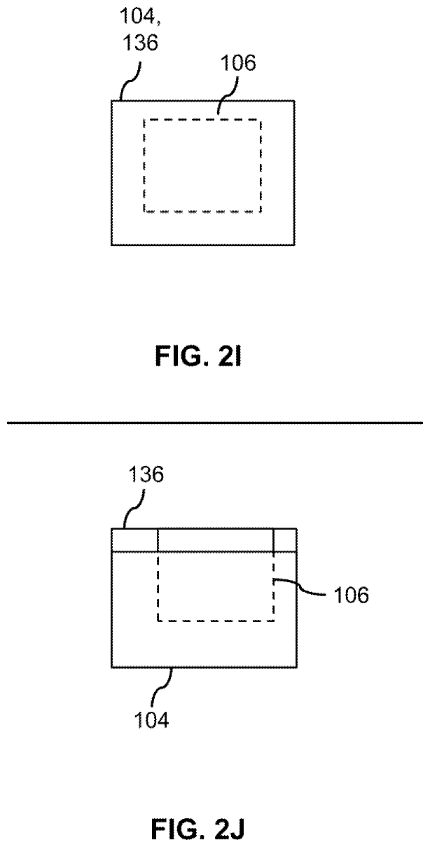

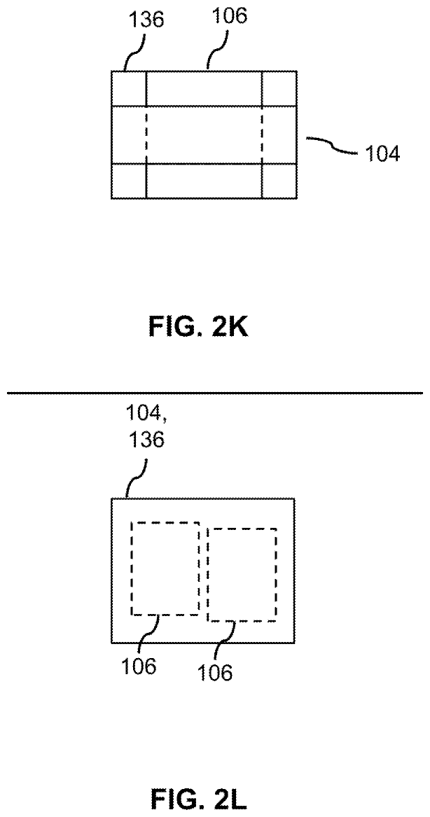

Referring generally to FIGS. 1A-2L, a module 100 is described, in accordance with one or more embodiments of the present disclosure. The module 100 may generally include a first die which is stacked above a second die on a printed circuit board, an interposer, or inside a substrate cavity, such that at least a portion of the second die is disposed between the first die and the PCB. An overall area of the floorplan of the PCB may be reduced when the dies are stacked over the top side of the PCB in the vertical direction. By arranging the module 100 as described herein, the size of the module 100 in the x and y directions may be reduced by up to 30 percent. In some instances, stacking the die in the vertical direction may increase the height of the module. For instance, the height of the module may be increased depending upon the relative height of the stacked dies and one or more surface mount technology (SMT) components. Embodiments of the present disclosure are also directed to minimizing the increase in height due to the die stacking. The overall height may thus remain the same or also be reduced. With the structure of the module 100, electrical performance may also be improved as a result of the potential shortened critical path length between functional dies. Improving the electrical performance may lead to reduced resistive-capacitive (RC) delay. Thermal performance may also be improved by stacking one flip chip die, which acts as a thermal spreader, on top of another thermal sensitive die. Thermal performance may also be improved by reducing a thermal path when placing a thermal sensitive die inside a substrate cavity.

In embodiments, the module 100 may be also be referred to as a radio frequency (RF) front-end module (FEM). The module 100 may be molded and EMI shielded for RF applications. The module 100 may be used in a number of radio frequency (RF) applications, such as, but not limited to, a radio frequency (RF) module of a mobile phone or another communication device. In such RF applications, designs of the module 100 may be sensitive to size and cost requirements. The module 100 may further include one or more filters, amplifiers, oscillators, and the like. In some instances, the RF front end is placed onto the motherboard of a communication device. The RF front end may be placed on the motherboard for filtering or amplifying a signal of the communication device. It is further contemplated that the module 100 may include applications other than as an RF module or an RF front end.

The module 100 may include one or more components, such as, but not limited to, a printed circuit board (PCB) 102, a die 104, a die 106, a surface-mounted technology (SMT) 108, a die 110, ball-grid array (BGA) 112, and/or a molding compound 113. The overall height for the module 100 may be determined by the PCB 102 thickness, the BGA 112 height, the die 104 thickness, the die 106 thickness, among other factors. The module 100 may also include interconnects 118, solder joints 120, interconnects 122, solder joints 124, cavity 126, wire bonds 128, wire bonds 130, die attach film 132, die attach film 134, interposers 136, molding compound 113, and/or intermediary molding compound 138.

The PCB 102 may include pads for coupling the die 104 and the die 106. For example, the metal layers 114 of the PCB 102 may be patterned to have solder bumps landed on a top surface of the PCB 102 and/or in the cavity 126. The solder bumps may be melted and wetted to the metal layers of the PCB during reflow, followed by cooling to form a solid joint with one or more of the interconnects 118 or the interconnects 122.

As used herein, a top surface of the PCB 102 may generally refer to a top insulating layer of the PCB. For example, see the top insulating layer depicted in FIG. 1D. Although not labelled, the exemplary configurations depicted in FIGS. 1A-1N may similarly include the top insulating layer 150. The top insulating layer 150 may also be referred to as a substrate layer. The top insulating layer 150 may generally include a low conductivity to electricity. The top insulating layer 150 may be formed by any electrically insulating material compatible with fabrication of printed circuit boards, such as, but not limited to, a resin material (e.g., epoxy (e.g., FR-4)), and the like. The top insulating layer 150 may include a metal layer (e.g., metal layer 114a) disposed on the top insulating layer 150. The metal layer disposed on the top insulating layer 150 may also be referred to as a trace. The metal layer may be formed from any electrically conductive material compatible with fabrication of printed circuit boards, such as, but not limited to, copper, gold, silver, aluminum, and the like. The metal layer may generally be fabricated by any printed circuit board fabrication process. The printed circuit board 102 may also include multiple layers of the metal layers and/or multiple layers of the insulating layers, such that the printed circuit board 102 may be considered a multilayer PCB. In embodiments, the PCB defines a cavity which may include a surface. As used herein, a surface of the cavity may similarly refer to an insulating layer of the PCB 102 which is lower than the top insulating layer.

The PCB 102 may be double-sided, including pads for coupling a die to a top surface of the PCB 102 and a bottom surface of the PCB 102. The PCB 102 may be a multilayer PCB including metal layers 114 separated by insulating layers. For example, the PCB 102 is depicted as including nine of the metal layers, although this is not intended to be limiting. The metal layers 114 may be formed of any electrically conductive material compatible with fabrication of printed circuit boards. For example, the material may include, but is not limited to, copper (Cu), gold (Au), silver (Ag) and/or aluminum (AI). The insulating layers may be formed of any electrically insulating material compatible with fabrication of printed circuit boards, such as prepreg material and/or resin-based dielectric material, for example. The metal layers 114 may be patterned to include circuitry between metal patterns (e.g., pads, trace, etc.) on the top surface of the PCB, metal patterns on the bottom surface of the PCB, and the BGA 112. For example, a top metal layer may connect to the die 104 or the die 106 by one or more copper pillars, solder bumps, wire bonds, and/or die attach films. By way of another example, a second metal layer may connect to the die 104 or the die 106 by one or more copper pillars, solder bumps, wire bonds, and/or die attach films, where the PCB includes a cavity. As used herein, cavity may refer to a hole cutout from a surface of the PCB through to one or more lower metal layers. The PCB may additionally include the vias 116, and the like. The vias 116 may provide interconnects between the metal layers 114. The vias 116 and the metal layers 114 may then provide routings between one or more of the die 104, the die 106, the SMT 108, the die 110, and/or the BGA 112. As may be understood, the various vias 116 and the metal layers 114 depicted are not intended to be limiting and are merely illustrative.

The die 106 may generally be disposed between the die 104 and the top surface of the printed circuit board (PCB) 102. In this regard, the die 104 may be stacked above the die 106. Stacking the die 104 above the die 106 may be advantageous in reducing the size of the module 100 in the x and y directions.

The die 104 and the die 106 may be referred to herein as a die, although this is not intended to be limiting. For example, the die 104 and the die 106 may include, but are not limited to, CMOS die, a silicon on insulator (SOI) die, an integrated passive device (IPD) die, a filter die, a bank of silicon capacitors, a discrete passive component, and the like. As used herein, passive may refer to an inductor, a resistor, a capacitor, and the like. The die may be selected from any of the above to achieve a desired functionality. A die thickness may be between 100 micrometers and 150 micrometers. The die 106 may generally be stacked over the die 104. The module 100 may further include the SMT 108 on the top surface of the PCB 102. The SMT 108 may include an inductor. The inductor may be taller than the die 104 and/or the die 106. For example, the inductor may include a component height (in the z-direction) of about 220 micrometers up to 320 micrometers, typically 250 micrometers for example. By stacking the die 106 on the die 104, the module 100 may advantageously use space above the die 106 which would otherwise be filled with molding compound, due to the height requirements of the SMT.

The PCB 102 may additionally include one or more of the die 110 attached to the bottom surface of the PCB 102. In this regard, the PCB 102 may be referred to as a double-sided PCB. In the depicted embodiment, the module 100 is a ball grid array (BGA) component. For example, the module 100 may include an array of solder balls, indicated by representative solder ball. The array of solder balls may be attached to a bottom surface of the PCB 102. The BGA 112 serves as the input/output (I/O) for the module 100, such as for communicating signals to and from a motherboard of a cell phone to the module 100. Alternatively, the module 100 may be a land grid array (LGA) component (which does not include the array of solder balls), or various other types of components, without departing from the scope of the present teachings.

The module 100 also includes the molding compound 113. The molding compound 113 may be formed of a reinforced or non-reinforced epoxy resin, an epoxy molding compound (EMC), and the like. The molding compound 113 may be applied using any process compatible with fabrication of semiconductor devices. For example, the molding compound 113 may be applied by one or more of as injection molding, transfer molding, and/or compression molding. The molding compound 113 generally protects the electronic components (e.g., the PCB 102, the die 104, the die 106, the SMT 108, etc.). The molding compound 113 may also provide additional structural support to the module 100. The molding compound 113 may also hermetically seal the electronic components and other circuitry within the module 100. The hermetic seal may protect against environmental elements, such as temperature and moisture. The molding compound 113 may be formed over the SMT 108, the die 106, and the top surface of the PCB 102. In some instances, the molding compound 113 is also formed over the die 104. In other instances, the molding compound 113 is formed around a portion of the die 104, with a top surface of the die 104 being exposed.

Optionally, grinding may be performed reduce a height of the die 104. In some instances, the top die may extend above a surface-mounted technology (SMT) 108 component. The overall height for this module is then limited based on the top die. By grinding a portion of the die, the module height may be reduced. For example, the die 104 may be exposed where the die 104 is flip chip mounted to the PCB such that the back of the die 104 is exposed at the top surface of the module. Additionally, the top surface of the die 104 may be exposed where the SMT 108 is disposed below the top surface of the die 104 such that the top surface of the die 104 may be exposed by grinding the molding compound 113 without grinding the SMT 108. Grinding the molding compound 113 to expose the top surface of the die 104 may be advantageous in reducing the overall height of the module 100, as compared to a module which has not been grinded down below the top surface of the die 104. The grinding may be performed for height management to reduce the overall height of the module. Where the module is grinded to expose the die, the grinding may include grinding a portion of the die. For example, a silicon bulk found on the back side of the die 104 may be grinded away. The grinding may remove between 30 to 45 micrometers. This is based on the die thickness before grinding, so that the die thickness after grinding will be reduced to a range of 130 micrometers to 205 micrometers. The benefit of grinding the die 104 is that a thicker die may be easier to pick and place onto the PCB 102 prior to grinding while also including a reduced height after grinding.

To be exposed may mean that the surface is not covered by the molding compound 113, but may or may not be covered by an EMI shield. For example, after the components are placed, the molding compound 113 may be over-molded, followed by grinding to a given height, followed by EMI shielding. The EMI shielding is not depicted herein.

The module 100 may include a marking (not depicted), such as a laser marking or ink marking. The laser marking may include letters, numbers, or characters visually indicating the series marking with a lot, date, assembly side, or machine-readable barcode and the like. The laser marking may be included on the molding surface area. The laser marking may have a certain depth. For example, a laser marking depth may be 40 micrometers. If the laser marking is performed on the molding surface, for example, there may be a minimum height requirement under that molding surface. A clearance must be maintained from the top surface for the marking depth. In embodiments, the laser marking may also be performed on top surface of the die 104 which is exposed. By laser marking the die 104, the minimum clearance requirement from the die surface may be shallower than the minimum clearance requirement from the molding surface when marking on the molding surface area. In this regard, the laser marking may be included in the silicon bulk of the die 104. Including the laser marking in the silicon bulk helps reduce the overall height of the module. In embodiments, marking on die 104 may be done by ink marking. In this regard, there may be no height clearance requirement for marking.

Although not depicted, the module 100 may include an external shield formed over the molding compound 113. The external shield may provide additional protection from environmental stress, as well as electromagnetic shielding from external sources. The external shield may be formed of a conductive material (e.g., metal). For example, the material may include, but is not limited to, stainless steel, copper (Cu), silver (Ag), gold (Au), and/or aluminum (AI). By way of another example, the material may include a combination of conductive and non-conductive materials, without departing from the present teachings.

In embodiments, the module 100 include one or more interconnects 118 (e.g., copper pillars) and one or more solder joints 120. The interconnects 118 may be formed of a copper material in a pillar shape and the solder joint 120 may be formed of a solder joint. The interconnect 118 together with the solder joint 120 may be referred to as a copper pillar structure and/or as a flip-chip mounting for the die 104. The height of the flip-chip mounting may be determined by measuring the height of the interconnect 118 together with the height of the solder joint 120. The interconnect 118 and solder joint 120 together may also be referred to herein as a taller pillar structure. In embodiments, the module 100 includes one or more wire bonds 128. The interconnects 118, solder joints 120, and/or the wire bonds 128 may generally provide an electrical connection for the die 104. The interconnects 118 and the solder joints 120 may provide a mechanical attachment for the die 104. In some instances, the interconnects 118 and the solder joints 120 provide both a mechanical attachment and an electrical connection. In some instances, the interconnects 118 and the solder joints 120 serve as mechanical attachment but carry no electrical signals.

In embodiments, the module 100 includes one or more interconnects 122 and one or more solder joints 124. The interconnects 122 may be formed of a copper material in a pillar shape. The interconnect 122 together with the solder joint 124 may be referred to as a copper pillar structure. The interconnect 122 and the solder joint 124 together may also be referred to herein as a shorter pillar structure and/or as a flip-chip mounting for the die 106. Similarly, the height of the flip-chip mounting may be determined by measuring the height of the interconnect 122 together with the height of the solder joint 124. In embodiments, the module 100 includes interconnects 122 and one or more solder joints 124. The interconnect 122 may be a under bump metallization (UBM) mainly formed of a nickel material, such that the interconnect 122 and solder joint 124 together may be referred to as a nickel bump. The interconnect 122 and the solder joint 124 together may also be referred to herein as a shorter bump structure. In embodiments, the module 100 includes one or more wire bonds 130. The interconnects 122, solder joints 124, and/or the wire bonds 130 may generally provide an electrical connection for the die 106. The interconnect 122 and the solder joints 124 may provide a mechanical attachment for the die 106. In some instances, the interconnects 122 and the solder joints 124 provide both a mechanical attachment and an electrical connection. In some instances, the interconnects 122 and the solder joints 124 serve as mechanical attachment but carry no electrical signals.

The relative heights of the flip-chip mounting for the die 104 and the flip-chip mounting for the die 106 are now described. In some embodiments, the flip-chip mounting for the die 104 may be taller than the flip-chip mounting for the die 106. The height for the flip-chip mounting may be determined relative to a respective mounting surface. Here, the respective mounting surface may refer to a specific metal layer to which the die 104 and/or the die 106 are flip-chip mounted. Providing the die 104 with a taller flip-chip mounting may allow the die 104 to be disposed over the die 106. In some embodiments, the flip-chip mounting for the die 104 may be taller than the flip-chip mounting for the die 106 when the die 104 is flip-chip mounted to a higher metal layer than the die 106. For example, FIG. 1A depicts the die 104 flip-chip mounted to the metal layer 114a of the PCB 102 by the interconnect 118 and the solder joint 120. FIG. 1A further depicts the die 106 flip-chip mounted to the metal layer 114b (e.g., PCB pad 140) of the PCB 102 by the interconnect 118 and the solder joint 120. The interconnect 118 and the solder joint 120 have a first height, when measured from the metal layer 114a. The interconnect 122 and the solder joint 124 have a second height, when measured from the metal layer 114b. As depicted, the first height is taller than the second height. Thus, the die 104 may be disposed over the die 106 due to the relative heights of the flip-chip mountings.

The interconnect 118 and solder joint 120 together and the interconnect 122 and solder joint 124 together may be substantially similar in function. The various interconnects and solder joints may provide an electrical or mechanical connection between the dies and the PCB 102. One difference between the interconnect 118 and solder joint 120 together and the interconnect 122 and solder joint 124 together is that the total height of the interconnect 122 and solder joint 124 together is significantly shorter than the total height of the interconnect 118 and solder joint 120 together. For example, the interconnect 118 may be a copper pillar with a height between 50 and 100 micrometers and the solder joint 120 may be a solder joint with a height around 20 micrometers. By way of another example, the interconnect 122 may be a nickel UBM with a height of 3 micrometers, and the solder joint 124 may be a solder joints with a height around 15 micrometers. By way of another example, the interconnect 122 may be a copper pillar with a height of 10 micrometers and the solder joint 124 may be a solder joint with a height around 15 micrometers. In some instances, PCB pad 140 thickness under the solder joint 124 may be thinner than PCB pad 142 thickness under the solder joint 120, such as 5 micrometers thinner, for example. The smaller pad thickness may be induced by etching during the PCB cavity formation process, or the like. The smaller pad thickness may be advantageous for further reducing the standoff height of the die 106.

The use of the nickel bump may be advantageous in achieving a bump size which is sufficiently small for reducing the standoff height of the die 106. Reducing the standoff height may be particularly advantageous where the die 104 is stacked above the die 106. The solder bumps may be wetted to pads of the PCB 102. As may be understood, the pads may be formed by selective plating or etching the metal layers during fabrication of the PCB 102. Other techniques for fabricating the metal layers to form the pads including other selective additive processes and etching processes may be incorporated without departing from the scope of the present teachings, as would be apparent to one skilled in the art.

The die 104 and the die 106 may each be rectangular. By being rectangular, each die includes two opposing ends. The opposing ends may also be referred to herein as opposing sides, lateral sides, and the like. In embodiments, the opposing ends of the die 104 may or may not extend beyond the opposing ends of the die 104. Where the opposing ends of the die 104 extend beyond the opposing ends of the die 106, the die 104 may be considered to be wider than the die 106. For example, the die 104 include an end 146a and an end 146b. The end 146a may oppose the end 146b (e.g., opposing ends 146). The die 106 may include an end 148a and an end 148b. The end 148a may oppose the end 148b (e.g., opposing ends 148). As depicted in FIG. 1A, the opposing ends 146 of the die 104 may extend beyond the opposing ends 148 of the die 106. Similarly, the die 104 may be narrower than the die 106. The opposing ends 146 may not extend beyond the opposing ends 148 when the die 104 is narrower than the die 106 (e.g., see FIG. 1E or FIG. 2E). The die 104 may also be wider than the die 106 while also not including the opposing ends 146 which extend beyond the opposing ends 148 (e.g., see FIG. 1D or 2F).

In embodiments, each of the opposing ends for each die is supported by the pillars. By being supported by the pillars, the die may be mechanically supported and may stand on the PCB stably. Furthermore, each of the two ends are not intended to be limited to a single pillar, but may include a number of pillars per each opposing end. It is further contemplated the dies may be supported on more than two ends, although this is not intended to be limiting. In embodiments, the die may be supported by the die attach films and then electrically connected by the wire bonding.

When assembling the stacked dies, the PCB 102 may be loaded into an assembly machine and held in place by a vacuum chuck. A pick and place machine may then place the dies and other components onto the surface of the PCB. When the module 100 includes the stacked dies, the pick and place machine may place the lowest die first and then place the upper die. In this regard, the pick and place machine require a specific sequencing of placement to achieve the stacked configuration. The distance between the outer most pad under the solder joint 124 of the die 106 and its neighboring pad under the solder joint 120 of the die 104 may be selected based on PCB manufacturing tolerance and/or placement accuracy tolerance.

In embodiments, the die 104 and the die 106 may be separated by a gap 144. The gap 144 may comprise an EMC molding material or an underfill material. Such material may be important for improving a reliability of the module. The gap 144 may generally include any dimension, such as, but not limited to, 35 micrometers. For example, the die 104 is depicted as being separated from the 106 by the gap 144 in FIGS. 1A-1C, 1F-1H, and 1K-1N.

In embodiments, the die 104 may be attached to the backside of the die 106 using die attach film. The die attach film may be an adhesive film having a thickness of between 5 micrometers and 10 micrometers.

In embodiments, the PCB 102 may define a cavity 126. The cavity 126 may be formed in the top side of a PCB 102 such that the top surface is not flat across the entire PCB 102. As may be understood, the cavity 126 may be formed from the PCB 102 by any suitable process, such as etching, laser ablation, or using patternable photosensitive materials. The depth of the cavity 126 may be selected based on a distance to the metal layers 114 below the top surface. For example, the depth of the cavity 126 may be selected to expose the second metal layer 114b. Exposing the metal layer 114b may be referred to as one-layer cavity depth. Higher layer cavity depths are contemplated but are not depicted herein, such as two-layer cavity depths and three-layer cavity depths. When the standoff height of the die 104 is a limiting factor with respect to the size of the module 100, the die 106 may be mechanically attached within the cavity 126. The die 106 may be mechanically attached within the cavity 126 by the interconnect 122 and the solder joint 124 or the die attach film 134. Attaching the die 106 within the cavity 126 lowers the standoff height of the die 106, as compared to attaching the die 106 on the top surface of the PCB 102. Where the die 104 is stacked above the die 106 and the die 106 is mechanically attached within the cavity 126, the standoff height of the die 104 may also be reduced. Reducing the standoff height of the die 104 may be beneficial in reducing the overall height of the module 100. In embodiments, the die 104 may also be attached within the cavity 126 by the interconnect 118 and solder joint 120, although this is not intended to be limiting. The die 104 may be attached to the top surface of the PCB 102 by the interconnect 118 while the die 106 is attached within the cavity 126, for achieving the reduced module height. The die 104 may be attached to the top surface of the die 106 by the die attach film 132 while the die 106 is attached within the cavity 126, for achieving the reduced module height. The reduction in height of the module 100 may correspond to the cavity depth, which may be about 37 micrometers, for example. It is further contemplated the cavity depth may be up to 50 micrometer or more.

In embodiments, the module 100 may include an interposer 136. As used herein, interposer may refer to an electrical interface between one or more components. The interposer 136 may include metal layers and insulating layers (not depicted). The metal layers of the interposer 136 may provide routing among the PCB 102, the die 104, and the die 106. The interposer 136 may be beneficial in increasing the I/O density for routing purposes. For example, the interposer 136 may have a finer line width and space, as compared to the PCB 102. The interposer 136 may be fabricated by redistribution layer (RDL) process, wafer level back-end-of-line process, and the like. Although the module 100 is described as including the interposer 136, this is not intended to be limiting.

Each of the die 104 and the die 106 may include a face. As used herein, a face may refer to a surface of a die. A face may include electrical interconnects for electrically coupling by pillars, bumps or wire bonds. Each of the die 104 and the die 106 may also include a back which is oppositely disposed to the face. The face of the dies may generally include an electrical connection between the dies and one or more components of the module 100. In some instances, the face or the back may include a mechanical attachment between the dies and one or more components of the module 100. The die 104 is thus electrically connected and mechanically attached to one or more components of the module 100. In some instances, the die 104 is electrically connected and mechanically attached to a first component, such as the top surface of the PCB 102, the cavity 126, the interposer 136. In some instances, the die 104 is electrically connected to a first component, such as the die 106, and electrically connected and mechanically attached to a second component, such as the top surface of the PCB 102. Similar to the die 104, the die 106 is electrically connected and/or mechanically attached to one or more components of the module 100. In some instances, the die 106 is electrically connected and mechanically attached to a first component, such as the top surface of the PCB 102, the bottom surface of the cavity 126, the interposer 136, or the die 104. In some instances, the die 106 is mechanically attached to a first component, such as the metal layer 114b inside the cavity 126, and electrically connected to a second component, such as the metal layer 114a as the top surface of the PCB 102.

A number of permutations for the electrical connections and mechanical attachments of the die 104 and the die 106 are now described. As may be understood, the various depictions of the permutations are not intended to be limiting and are merely provided for illustration.

In embodiments, the die 104 may be electrically connected and mechanically attached to the metal layers 114 by a flip-chip mounting. The module 100 may include one or more interconnects 118 and one or more solder joints 120. The interconnect 118 and the solder joints 120 may electrically connect and mechanically attach the die 104 to the one or more of the metal layers 114 of the PCB 102. Such arrangement may also be referred to herein as a flip-chip mounting between the die 104 and the PCB 102. The die 104 may be flip-chip mounted to the metal layer 114a on the top surface of the PCB or the metal layer 114b below the metal layer 114a (i.e., within the cavity 126). For example, FIG. 1A, FIG. 1C, and FIGS. 1F-1I depict a flip-chip mounting between the die 104 and the metal layer 114a disposed on the top surface of the PCB 102. By way of another example, FIG. 1B depicts a flip-chip mounting between the die 104 and the metal layer 114b disposed in the cavity 126 of the PCB 102. As used herein, “flip-chip mounting” may refer to connecting a face of a die to another component by one or more interconnects, copper pillars, and/or one or more solder joints.

In embodiments, the die 104 may be electrically connected to the metal layers 114 by wire bonding and mechanically attached to the die 106. The module 100 may include the wire-bonds 128 and the die attach film 132. The wire-bonds 128 may electrically connect the die 104 onto the metal layer 114a of the top surface of the PCB 102. The die attach film 132 may mechanically attach the die 104 to the die 106. For example, FIGS. 1D-1E depict the wire-bonds 128 and die attach film 132 as described.

In embodiments, the die 104 may be electrically connected and mechanically attached to the interposer 136. The module 100 may include the interconnect 118 electrically connecting and mechanically attaching the die 104 to the interposer 136. The interconnects 118 may be pre-existing pillars which are formed on the interposer 136 prior to molding to form the connection to the die 104. The die 104 may be attached to the surface of the second molding compound 138 through a solder or flux printing process. The interconnect 118 may be formed by through mold vias. The interconnects 118 may be connected onto pads of the interposer 136. The interposer 136 may then be electrically connected and mechanically attached to the metal layer 114 of the PCB and interconnect the die 104 to the PCB 102. For example, FIGS. 1K-1N depict the die 104 connected to the interposer 136 as described.

In embodiments, the die 106 may be electrically connected and mechanically attached to the metal layers 114 by a flip-chip mounting. The module 100 may include one or more interconnects 122 (e.g., pillars or UBM) and one or more solder joints 124. The interconnects 122 and the solder joint 124 may electrically connect and mechanically attach the die 106 to the one or more of the metal layers 114 of the PCB 102. Such arrangement may also be referred to herein as a flip-chip mounting between the die 106 and the PCB 102. The die 106 may be flip-chip mounted to the metal layer 114a on the top surface of the PCB or the metal layer 114b below the metal layer 114a (i.e., within the cavity 126). For example, FIGS. 1F-1G depict a flip-chip mounting between the die 106 and the metal layer 114a disposed on the top surface of the PCB 102. By way of another example, FIGS. 1A-1D depicts a flip-chip mounting between the die 106 and the metal layer 114b disposed in the cavity 126 of the PCB 102.

In embodiments, the die 106 may be electrically connected to the metal layers 114 by wire bonding and mechanically attached to the PCB 102 by a die attach film. The module 100 may include one or more wire-bonds 130 and a die attach film 134. The wire-bonds 130 may electrically connect the die 104 to the metal layer 114a on the top surface of the PCB 102. The die attach film 134 may mechanically attach the die 104 to the top surface of the PCB 102 or mechanically attach the die 106 within the cavity 126. For example, FIG. 1E, depicts the die attach film 134 mechanically attaching the die 106 within the cavity 126 with the wire bonds 130 electrically connecting to the metal layer 114a of the top surface of the PCB. In this example, the ends 148 of the die 106 extend beyond the ends 146 of the die 104 for receiving the wire bonds 130. In some embodiments, the die 104 includes one or more of the ends 148 which extend beyond the die 104 for receiving the wire bonds 130.

In embodiments, the die 106 may be electrically connected and mechanically attached to the die 104. The die 106 may be electrically connected and mechanically attached to the die 104 by a flip-chip mounting. The module 100 may include the interconnects 122 (e.g., pillar or UBM) and the solder joint 124 between the die 104 and the die 106. In this configuration, the die 104 may include mechanical support and electrical interconnects (e.g., signal paths) between the die 106 and the PCB 102. The die 104 may then act as an interconnect to the PCB 102 for the die 106. For example, FIGS. 1H-1J depict the flip-chip mounting between the die 106 and the die 104. The flip-chip mounting between the die 106 and the die 104 may also be referred to as a face-to-face connection, in which the face of the die 106 is oriented towards the face of the die 104. Providing the face-to-face connection may provide a beneficial electrical performance for functions, because the electrical path between the die 104 and the die 106 is shorter.

In embodiments, the die 106 may be electrically connected and mechanically attached to the interposer 136. The die 106 may be electrically connected and mechanically attached to the interposer 136 by the interconnect 122 (e.g., pillar or UBM) and the solder joints 124. The interposer 136 may then be electrically connected and mechanically attached to the metal layer 114 of the PCB and interconnect the die 106 to the PCB 102. For example, FIGS. 1K-1N depict the die 106 connected to the interposer 136 as described.

One or more exemplary configurations of the module 100 are now described. As may be understood, the various numerical ranges of the exemplary ranges are not intended to be limiting and are merely provided for illustration.

Referring now in particular to FIG. 1A, an exemplary module 100a is described. The exemplary module 100a includes die stacking with the die 106 coupled within the cavity 126 of the PCB. The die 106 is flip-chip mounted into the cavity 126. The die 104 is then flip-chip mounted onto the top surface of the PCB 102. The solder joints 120 and the solder joints 124 may then be formed at the same time by reflow at once along with other dies and components placed on PCB top surface (i.e., the SMT 108), thereby not introducing additional reflow steps nor extra assembly cost. The die 104 is connected by the interconnects 118 along with solder joints 120 and the die 106 is connected by the interconnects 122 along with solder joints 124. To realize this configuration, the total height of interconnect 122 and solder joint 124 are shorter than the total height of interconnect 118 and solder joint 120. For example, interconnect 122 and solder joint 124 together may be shorter copper pillars or nickel bumps and interconnect 118 and solder joint 120 together may be taller copper pillars. The die 104 and the die 106 may be fully or partially overlapped (see FIGS. 2A-2D, for example). The die 106 may include multiple dies, bank of Si capacitors, IPD, or any combination therein. A shorter bump structure (for example, 3 micrometers of nickel and 15 micrometer of plated solder) along with 70 micrometer bump diameter and 110 micrometer bump pitch may be used for the interconnects 122 and solder joints 124 of the die 106. A taller bump structure (for example, 80 micrometers of copper and 20 micrometers of plated solder) along with 70 micrometers bump diameter and 110 micrometer bump pitch may be used for the interconnects 118 and solder joints 120 of the die 104. A depth for the cavity 126 may be around 37 micrometers. A distance between the outer most pad of the die 106 and its neighboring pad of the die 104 may be 155 micrometers or greater. A thickness for the die 106 may vary from 50 micrometers to 105 micrometers. A thickness for the die 104 may vary from 100 micrometers to 155 micrometers. The die 104 and the die 106 may include an airgap in between. The airgap may be filled with underfill or molding during one or more fabrication steps to form the gap 144. The airgap may be around 35 micrometers, making it feasible for stacking the die 104 on the die 106. The clearance between the top surface of the die 104 and the top surface of the molding compound may be around 30 micrometers.

Referring now in particular to FIG. 1B, an exemplary module 100b is described. The exemplary module 100b includes die stacking with the die 104 and the die 106 coupled within the cavity 126. Notably, the die 104 of the exemplary module is coupled within the cavity 126. For example, the die 106 is flip-chip mounted into the cavity 126. The die 104 is then flip-chip mounted into the cavity 126. The solder joint 120 and the solder joint 124 may then be formed at the same time through one reflow step along with other dies and components placed on PCB top surface (i.e., the SMT 108), thereby not introducing additional reflow steps and extra assembly cost. The die 104 and the die 106 may be fully or partially overlapped (see FIGS. 2A-2D, for example). The die 106 may include multiple dies, bank of Si capacitors, IPD, or any combination therein. A shorter bump structure (for example, 3 micrometers of nickel and 15 micrometers of plated solder) along with 70 micrometers bump diameter and 110 micrometer bump pitch may be used for the interconnects 122 (e.g., pillars or UBM) and solder joints 124 of the die 106. A taller bump structure (for example, 80 micrometers of copper and 20 micrometers of plated solder) along with 70 micrometers bump diameter and 110 micrometer bump pitch may be used for the interconnects 118 and solder joints 120 of the die 104. A depth for the cavity 126 may be around 37 micrometers. A distance between the outer most pad of the die 106 and its neighboring pad of the die 104 may be 155 micrometers or greater. A thickness for the die 106 may vary from 50 micrometers to 105 micrometers. A thickness for the die 104 may vary from 100 micrometers to 155 micrometers. The die 104 and the die 106 may include an airgap in between which may be filled with underfill or molding. The airgap may be around 35 micrometers, making it feasible for stacking the die 104 on the die 106. The clearance between the top surface of the die 104 and the top surface of the molding compound may be around 30 micrometers.

Referring now in particular to FIG. 1C, an exemplary module 100c is described. The exemplary module 100c includes die stacking with the die 106 coupled within the cavity 126 and a top surface of the die 104 exposed. The top surface of the die 104 is exposed and not covered by the molding compound 113. The die 106 is flip-chip mounted into the cavity 126. The die 104 is then flip-chip mounted onto the top surface of the PCB 102. The solder joint 120 and the solder joint 124 may then be formed at the same time by one step reflow along with other dies and components placed on PCB top surface (i.e., the SMT 108), thereby not introducing extra assembly cost. A one step reflow may refer to where all of the various joints are reflowed in a single step. The molding compound 113 may then be over molded and grinded to expose the die 104. As used herein, over molding may refer to molding above a desired height. The over molding may then be ground to the desired height by the grinding. The die 104 and the die 106 may be fully or partially overlapped (see FIGS. 2A-2D, for example). The die 106 may include multiple dies, bank of Si capacitors, IPD, or any combination therein. A shorter bump structure (for example, 3 micrometers of nickel and 15 micrometers of plated solder) along with 70 micrometers bump diameter and 110 micrometer bump pitch may be used for the interconnect 122 (e.g., pillars or UBMs) and solder joints 124 of the die 106. A taller bump structure (for example, 80 micrometers of copper and 20 micrometers of plated solder) along with 70 micrometers bump diameter and 110 micrometer bump pitch may be used for the interconnects 118 and solder joints 120 of the die 104. A depth for the cavity 126 may be around 37 micrometers. A distance between the outer most pad of the die 106 and its neighboring pad of the die 104 may be 155 micrometers or greater. A thickness for the die 106 may vary from 50 micrometers to 105 micrometers. A thickness for the die 104 may vary from 160 micrometers to 250 micrometers before grinding, and may vary from 130 micrometers to 205 micrometers after grinding. The die 104 and the die 106 may include an airgap in between which may be filled with underfill or molding. The airgap may be around 35 micrometers, making it feasible for stacking the die 104 on the die 106. The backside of the die 104 is exposed by grinding, which helps further reduce the height of the module 100. In embodiments, the top surface of the die 104 may include a laser marking or ink marking.

Referring now in particular to FIG. 1D, an exemplary module 100d is described. The exemplary module 100d includes die stacking with interconnect 122 (e.g., pillars or UBMs) and solder joints 124 connecting the die 106 within the cavity 126 and wire bonds 128 connecting the die 104 with the PCB 102. The die 106 is flip-chip mounted into the cavity 126. The PCB 102 and the die 106 are then reflowed. The die 104 is then attached onto the die 106 using the die attach film 132. The die 104 is then connected to the PCB 102 by the wire bonds 128. The die 106 is thus electrically connected through the interconnect 122 and solder joints 124 while the die 104 is connected through the wire bonds 128. Thus, the die 104 is stacked over the die 106, the die 104 is connected to the PCB 102 by the wire bonds 128, the die 104 is mechanically attached to the die 106 by the die attach film 132, and the die 106 is connected inside cavity 126 of the PCB 102 by the interconnect 122 and solder joint 124. The die 104 may be smaller than, bigger than, or of equal size to the die 106 (see FIGS. 2A, 2H, for example). The die 104 may be multiple dies, bank of Si capacitors, IPD, or any combination therein. The die 104 and the die 106 may overlap as much as possible for the sake of module size reduction as well as ease in the wire bonding process. A shorter bump structure (for example, 3 micrometers of nickel and 15 micrometers of plated solder) along with 70 micrometers bump diameter and 110 micrometer bump pitch may be used for the interconnect 122 and the solder joints 124s of the die 106. A depth for the cavity 126 may be around 37 micrometers. A distance between the outer most pad of the die 106 and the outermost bond pad of the die 104 may be 170 micrometers or greater (from pad edge to pad edge). A thickness for the die 106 may vary from 50 micrometers to 150 micrometers. A thickness for the die 104 may vary from 50 micrometers to 100 micrometers. The clearance between the top surface of the die 104 and the top surface of the molding compound may be around 85 micrometers.

Referring now in particular to FIG. 1E, an exemplary module 100e is described. The exemplary module 100e includes die stacking with wire bonds 130 connecting the die 106 with the PCB 102 and wire bonds 128 connecting the die 104 with the PCB 102. The exemplary module 100e includes the wire bonds 130 and the die attach film 134. The die 106 is attached to metal layer 114b inside the substrate cavity 126 using the die attach film 134. The die 104 is then attached onto the die 106 using the die attach film 132. The die 104 and the die 106 are then connected to the metal layer 114a on the top surface of PCB 102 by the wire bonds 128 and the wire bonds 130. Thus, the die 104 is electrically connected to the PCB 102 by the wire bonds 128, the die 104 is attached to the die 106 by the die attach film 132, the die 106 is electrically connected to the PCB 102 by the wire bonds 130, and the die 106 is attached to metal layer 114b within the cavity 126 of the PCB 102 by the die attach film 134. The die 106 is not fully covered by the die 104 (see FIGS. 2E-2G, for example) so that the wire bonds may be formed. The die 104 may be multiple dies, bank of Si capacitors, IPD, or any combination therein. A depth for the cavity 126 may be around 37 micrometers. A thickness for the die 106 may vary from 50 micrometers to 150 micrometers. A thickness for the die 104 may vary from 50 micrometers to 100 micrometers. The clearance between the top surface of the die 104 and the top surface of the molding compound 113 may be around 85 micrometers.

Referring now in particular to FIG. 1F, an exemplary module 100f is described. The exemplary module 100f may include die stacking on a top surface of the PCB 102. The exemplary module 100f includes the interconnects 122 and solder joints 124 which are connected to the metal layer 114a. The die 106 is flip-chip mounted onto the top surface of the PCB 102. The die 104 is then flip-chip mounted onto the top surface of the PCB 102. The solder joint 120 and the solder joint 124 may then be formed through one step reflow at the same time along with other dies and components placed on PCB top surface (i.e., the SMT 108), thereby not introducing extra assembly cost. The die 104 and the die 106 may be fully or partially overlapped (see FIGS. 2A-2D, for example). The die 106 may include multiple dies, bank of Si capacitors, IPD, or any combination therein. A shorter interconnect structure (for example, 3 micrometers of nickel and 15 micrometers of plated solder) along with 70 micrometer bump diameter and 120 micrometer bump pitch may be used for the interconnect 122 and the solder joints 124 of the die 106. An even taller interconnect structure (for example, 100 micrometers of copper and 20 micrometers of plated solder) along with 70 micrometer bump diameter and 120 micrometer bump pitch may be used for the interconnects 118 and the solder joints 120 of the die 104. A distance between the edge of the die 106 and its neighboring pad of the die 104 may be 80 micrometers or greater. A thickness for the die 106 may vary from 50 micrometers to 70 micrometers. A thickness for the die 104 may vary from 120 micrometers to 155 micrometers. The airgap between the die 104 and the die 106 before underfill or molding may be around 35 micrometers, making it feasible for die stacking. The clearance between the top surface of the die 104 and the top surface of the molding compound 113 may be around 30 micrometers.

Referring now in particular to FIG. 1G, an exemplary module 100g is described. The exemplary module 100g may include die stacking on the top surface of the PCB 102 with the top surface of the die 104 exposed. The die 106 is flip-chip mounted onto the top surface of the PCB 102. The die 104 is then flip-chip mounted onto the top surface of the PCB 102. The solder joints 120 and the solder joints 124 may then be formed through one step reflow at the same time along with other dies and components placed on PCB top surface (i.e., the SMT 108), thereby not introducing extra assembly cost. The molding compound 113 may then be over molded and grinded to expose the top surface of the die 104. The die 104 and die 106 may be fully or partially overlapped (see FIGS. 2A-2D, for example). The die 106 may be multiple dies, bank of Si capacitors, IPD, or any combination therein. A shorter interconnect structure (for example, 3 micrometers of nickel and 15 micrometers of plated solder) along with 70 micrometer bump diameter and 120 micrometer bump pitch may be used for the interconnect 122 and the solder joints 124 of die 106. An even taller interconnect structure (for example, 100 micrometers of copper and 20 micrometers of plated solder) along with 70 micrometer bump diameter and 120 micrometer bump pitch may be used for the interconnects 118 and the solder joints 120 of die 104. A distance between the edge of the die 106 and its neighboring pad of the die 104 may be 80 micrometers or greater. A thickness for the die 106 may vary from 50 micrometers to 70 micrometers. A thickness for the die 104 may vary from 140 micrometers to 250 micrometers before mold grinding and from 110 micrometer to 185 micrometers after grinding. The airgap between the die 104 and the die 106 before underfill or molding may be around 35 micrometers, making it feasible for die stacking. The backside of the die 104 is exposed by grinding the molding compound 113, which helps further reduce the height of the module 100. In embodiments, the top surface of the die 104 may include a laser marking or ink marking.

Referring now in particular to FIG. 1H, an exemplary module 100h is described. The exemplary module 100h may include die stacking in a face-to-face configuration. The die 106 is flip-chip mounted to the face side of the die 104 and reflowed to form a diced die stack. The diced die stack may then be flip-chip mounted onto the top surface of the PCB by the interconnect 118 and solder joint 120 and reflowed. Thus, the die 106 is connected to the die 104 by the interconnect 122 solder joint 124 in a face-to-face configuration and the die 104 is connected to the PCB 102 by the interconnect 118 and solder joint 120. The die 104 and die 106 may be fully or partially overlapped (see FIGS. 2A-2D, for example). The die 106 may be multiple dies, bank of Si capacitors, IPD, or any therein. A shorter interconnect structure (for example, 3 micrometers of nickel and 15 micrometers of plated solder) along with 70 micrometer bump diameter and 120 micrometer bump pitch may be used for the interconnect 122 (e.g., UBM) and the solder joints 124 of the die 106. An even taller interconnect structure (for example, 100 micrometers of copper and 20 micrometers of plated solder) along with 70 micrometer bump diameter and 120 micrometer bump pitch may be used for the interconnects 118 and the solder joints 120 of the die 104. A distance between the edge of the die 106 and its neighboring pad of the die 104 may be 80 micrometers or greater. A thickness for the die 106 may vary from 50 micrometers to 70 micrometers. A thickness for the die 104 may vary from 120 micrometers to 155 micrometers. The airgap between the die 106 and the top surface of the PCB before underfill or molding may be around 35 micrometers, making it feasible for die stacking. The clearance between the top surface of the die 104 and the top surface of the molding compound 113 may be around 30 micrometers.

Referring now in particular to FIG. 1I, an exemplary module 100i is described. The exemplary module 100i may include die stacking in a face-to-face configuration with a top surface of the die 104 exposed. The die 106 is flip-chip mounted to the die 104 and reflowed to form a diced die stack. The diced die stack is then flip-chip mounted onto the top surface of the PCB 102 surface by the interconnects 118 and reflowed. The molding compound 113 is then over molded and grinded to expose the top surface of the die 104. The die 104 and the die 106 may be fully or partially overlapped (see FIGS. 2A-2D, for example). The die 106 may be multiple dies, bank of Si capacitors, IPD, or any combination therein. A shorter interconnect structure (for example, 3 micrometers of nickel and 15 micrometers of plated solder) along with 70 micrometer bump diameter and 120 micrometer bump pitch may be used for the interconnect 122 and the solder joints 124 of the die 106. An even taller interconnect structure (for example, 100 micrometers of copper and 20 micrometers of plated solder) along with 70 micrometer bump diameter and 120 micrometer bump pitch may be used for the interconnects 118 and the solder joints 120 of the die 104. A distance between the edge of the die 106 and its neighboring pad of the die 104 may be 80 micrometers or greater. A thickness for the die 106 may vary from 50 micrometers to 70 micrometers. A thickness for the die 104 may vary from 110 micrometer to 185 micrometers after grinding. The airgap between die 106 and PCB top surface before underfill or molding may be around 35 micrometers, making it feasible for die stacking. The backside of the die 104 is exposed by grinding the molding compound 113, which helps further reduce the height of the module 100. In embodiments, the top surface of the die 104 may include a laser marking or ink marking.

Referring now in particular to FIG. 1J, an exemplary module 100j is described. The exemplary module 100j may include die stacking in a face-to-face configuration with (not depicted in FIG. 1J) or without a top surface of the die 104 exposed inside a PCB cavity. The die 106 is flip-chip mounted to the die 104 and reflowed to form a diced die stack. The diced die stack is then flip-chip mounted to the metal layer 114b within the cavity 126 by the interconnects 118 and reflowed. The molding compound is 113 is then over molded and grinded to expose or not expose the top surface of the die 104. The die 104 and the die 106 may be fully or partially overlapped (see FIGS. 2A-2D, for example). The die 106 may be multiple dies, bank of Si capacitors, IPD, or any combination therein.

Referring now in particular to FIG. 1K, an exemplary module 100k is described. The exemplary module 100k may include die stacking on the interposer 136. The die 106 is flip-chip mounted to the interposer 136 followed by reflow, molding to form the intermediary molding compound 138, and grinding. The die 104 is then flip-chip mounted to the stack including interposer 136 and the die 106. Thus, the die 104 and the die 106 may be stacked over the interposer 136. The interposer 136 may then be mounted to the top surface of the PCB 102. The die 104 and die 106 may be fully or partially overlapped and the interposer 136 may fully overlap the die 104 and the die 106 (see FIGS. 21-2L, for example). Both of the interconnect 118 and the interconnect 122 are fully enclosed by the intermediary molding compound 138. The die 106 may be multiple dies, bank of Si capacitors, IPD, or a combination of any of them. The interconnects 118 may be pre-existing copper pillars which are formed on interposer 136 before molding. The connection between the die 104 and the stacking including the interposer 136 and the die 106 may be formed by a solder or flux printing process followed by reflow. The taller interconnect structure (for example, 100 micrometers of copper and 20 micrometers of plated solder) along with 70 micrometer bump diameter and 120 micrometer bump pitch may be used for the interconnects 118 and the solder joints 120 of the die 104. Alternatively, the interconnects 118 may be through mold vias (TMV) filled with conductive metals (e.g., plated copper, tungsten, etc.) after the intermediary EMC is formed, grinded, and drilled. A shorter interconnect structure (for example, 3 micrometer of nickel and 15 micrometers of plated solder) along with 70 micrometer bump diameter and 120 micrometer bump pitch may be used for the interconnect 122 and the solder joints 124 of the die 106. The thickness for the interposer 136 may vary from 30 micrometers to 100 micrometers. The die 106 thickness may vary from 45 micrometers to 155 micrometers. The die 104 thickness may vary from 50 micrometers to 160 micrometers. The distance between the edge of the die 106 and its neighboring pad of the die 104 may be 80 micrometers or greater. The airgap between the die 106 and the die 104 before underfill or molding may be around 10 to 20 micrometers. The clearance between the top surface of the die 104 and the top surface of the molding compound 113 may be 30 micrometers.

Referring now in particular to FIG. 1L, an exemplary module 100l is described. The exemplary module 100l may include die stacking on the interposer 136 with the top surface of the die 104 exposed. The die 106 is flip-chip mounted to the interposer 136 followed by reflow, molding of the intermediary molding compound 138, and grinding. The die 104 is then flip-chip mounted to the stack including interposer 136 and the die 106. The interposer 136 is then mounted to the top surface of the PCB 102. The molding compound 113 is then over molded and grinded to expose the top surface of the die 104. The die 104 and die 106 may be fully or partially overlapped and the interposer 136 may fully overlap the die 104 and the die 106 (see FIGS. 21-2L, for example). Both of the interconnect 118 and the interconnect 122 are fully enclosed by the intermediary molding compound 138. The die 106 may be multiple dies, bank of Si capacitors, IPD, or any combination therein. The interconnects 118 may be pre-existing copper pillars which are formed on the interposer 136 before molding. The connection between the die 104 and the stack including the interposer 136 and the die 106 may be formed by a solder or flux printing process followed by reflow. The taller interconnect structure (for example, 100 micrometers of copper and 20 micrometers of plated solder) along with 70 micrometer bump diameter and 120 micrometer bump pitch may be used for the interconnects 118 and the solder joints 120 of the die 104. Alternatively, the interconnects 118 may be through mold vias filled with metals (e.g., plated copper, tungsten, etc.) after the intermediary EMC is formed, grinded, and drilled. A shorter interconnect structure (for example, 3 micrometers of nickel and 15 micrometers of plated solder) along with 70 micrometer bump diameter and 120 micrometer bump pitch may be used for the interconnect 122 and the solder joints 124 of the die 106. The thickness for the interposer 136 may vary from 30 micrometers to 100 micrometers. The die 106 thickness may vary from 45 micrometers to 155 micrometers. The die 104 thickness may vary from 80 micrometers to 190 micrometers. The distance between the edge of the die 106 and its neighboring pad of the die 104 may be 80 micrometers or greater. The airgap between the die 106 and the die 104 before underfill or molding may be around 10 to 20 micrometers. The backside of the die 104 is exposed by grinding the molding compound 113, which helps further reduce the height of the module 100. In embodiments, the top surface of the die 104 may include a laser marking or ink marking.

Referring now in particular to FIG. 1M, an exemplary module 100m is described. The exemplary module 100m may include die stacking on the interposer 136 with the top surface of the die 104 exposed. The die 106 is flip-chip mounted to the interposer 136 followed by reflow, molding of the intermediary molding compound 138, and grinding. The die 104 is then flip-chip mounted to the stack including the interposer 136 and the die 106. The interposer 136 is then mounted to the metal layer 114b in the cavity 126. The molding compound 113 is then over molded and grinded to expose the top surface of the die 104. Alternatively, the molding compound 113 may grinded less, such that the top surface of the die 104 is not exposed (not depicted in FIG. 1M).

Referring now in particular to FIG. 1N, an exemplary module 100n is described. As an alternative process flow to the exemplary module 100k, the die 106 may be flip-chip mounted to the interposer 136, followed by the die 104 being flip-chip mounted to the interposer, followed by reflow and molding of the intermediary molding compound 138. In this regard, the intermediary molding compound 138 may encompass the die 104, the die 106, and the top surface of the interposer 136. The interposer 136 may then be mounted to the top surface of the PCB 102.

Referring generally again to FIGS. 1A-2L.

The module may also include an under-bump metallization (UBM) layer. The UBM layer serves as an adhesion layer and a barrier layer between the die and the copper pillars or between the die and the nickel bumps. The UBM layer may be titanium, titanium tungsten, tantalum, and the like.

As used herein, directional terms such as “top,” “bottom,” “over,” “under,” “upper,” “upward,” “lower,” “down,” and “downward” are intended to provide relative positions for purposes of description, and are not intended to designate an absolute frame of reference. Various modifications to the described embodiments will be apparent to those with skill in the art, and the general principles defined herein may be applied to other embodiments.

It is understood that the specific order or hierarchy of steps in the methods, operations, and/or functionality disclosed are examples of exemplary approaches. Based upon design preferences, it is understood that the specific order or hierarchy of steps in the methods, operations, and/or functionality can be rearranged while remaining within the scope of the inventive concepts disclosed herein. The accompanying claims may present elements of the various steps in a sample order, and are not necessarily meant to be limited to the specific order or hierarchy presented. It is to be understood that embodiments of the methods according to the inventive concepts disclosed herein may include one or more of the steps described herein. Further, such steps may be carried out in any desired order and two or more of the steps may be carried out simultaneously with one another. Two or more of the steps disclosed herein may be combined in a single step, and in some embodiments, one or more of the steps may be carried out as two or more sub-steps. Further, other steps or sub-steps may be carried in addition to, or as substitutes to one or more of the steps disclosed herein.

From the above description, it is clear that the inventive concepts disclosed herein are well adapted to carry out the objects and to attain the advantages mentioned herein as well as those inherent in the inventive concepts disclosed herein. While presently preferred embodiments of the inventive concepts disclosed herein have been described for purposes of this disclosure, it will be understood that numerous changes may be made which will readily suggest themselves to those skilled in the art and which are accomplished within the broad scope and coverage of the inventive concepts disclosed and claimed herein.

What is claimed:

1. A module comprising:
a printed circuit board (PCB) including a plurality of metal layers; wherein a first metal layer of the plurality of metal layers is disposed on a top insulating layer of the PCB;
a first die electrically coupled to the PCB by a first flip-chip mounting;
a second die electrically coupled to the PCB by a second flip-chip mounting;
wherein at least a portion of the second die is disposed between the first die and the PCB such that the first die is stacked over the second die; wherein the first die is separated from the second die by a gap; wherein a height of the first flip-chip mounting is taller than a height of the second flip-chip mounting; wherein at least two opposing ends of the first die extend beyond the second die; wherein the first flip-chip mounting mechanically supports the at least two opposing ends of the first die;
a component electrically coupled to the first metal layer; and
a molding compound formed over the component, the second die, and the top insulating layer of the PCB.

2. The module of claim 1, wherein the PCB defines a cavity; wherein a second metal layer of the plurality of metal layers is disposed on a bottom surface of the cavity; wherein the second flip-chip mounting is between the second die and the second metal layer.

3. The module of claim 2, wherein the first flip-chip mounting is between the first die and the first metal layer.

4. The module of claim 2, wherein the first flip-chip mounting is between the first die and the second metal layer.

5. The module of claim 2, wherein at least a third metal layer of the plurality of metal layers is disposed between the first metal layer and the second metal layer.

6. The module of claim 2, wherein the first flip-chip mounting comprises a first plurality of interconnects on the top insulating layer of the PCB; wherein the second flip-chip mounting comprises a second plurality of interconnects in the cavity; wherein a height of the first plurality of interconnects is greater than a height of the second plurality of interconnects, wherein the first plurality of interconnects includes pillars.

7. The module of claim 1, wherein the first flip-chip mounting is between the first die and the first metal layer; wherein the second flip-chip mounting is between the second die and the first metal layer.

8. The module of claim 1, further comprising an interposer; wherein the interposer is electrically coupled between the first die and the first metal layer; wherein the interposer is electrically coupled between the second die and the first metal layer; wherein the first flip-chip mounting is between the first die and a top surface of the interposer; wherein the second flip-chip mounting is between the second die and the top surface of the interposer.

9. The module of claim 8, further comprising a second molding compound; wherein the second molding compound encloses the second flip-chip mounting; wherein the first flip-chip mounting comprises a plurality of vias through a portion of the second molding compound.

10. The module of claim 8, further comprising a second molding compound; wherein the second molding compound encloses the second die and the second flip-chip mounting; wherein the first flip-chip mounting comprises a plurality of vias through the second molding compound.

11. The module of claim 1, wherein the molding compound is formed over the first die.

12. The module of claim 1, wherein the molding compound is formed around the first die; wherein a top surface of the component is disposed below a top surface of the first die; wherein the top surface of the first die is exposed such that the molding compound is not formed over the top surface of the first die for reducing a height of the module; wherein the top surface is exposed by grinding the molding compound.

13. The module of claim 1, wherein the first flip-chip mounting comprises a plurality of copper pillars; wherein the second flip-chip mounting comprises a plurality of nickel bumps; wherein the plurality of copper pillars are taller than the plurality of nickel bumps.

14. The module of claim 1, further comprising a third die electrically coupled to the top insulating layer of the PCB; wherein at least a portion of the third die is disposed between the first die and the PCB; wherein the second die comprises at least one of a bank of silicon capacitors or an integrated passive device; wherein the PCB comprises a bottom surface disposed opposite to the top insulating layer; further comprising a plurality of ball grid array (BGA) balls coupled to the bottom surface.

15. A module comprising:
A printed circuit board (PCB) including a plurality of metal layers; wherein the PCB defines a cavity; wherein a first metal layer of the plurality of metal layers is disposed on a top insulating layer of the PCB;
a first die electrically coupled to the first layer of the PCB by a first wire-bond;
a second die electrically coupled to the PCB; wherein at least a portion of the second die is disposed between the first die and the PCB such that the first die is stacked over the second die; wherein the first die is attached to the second die by a first die attach film; wherein the first die is mechanically supported by the die attach film;
a component electrically coupled to the first metal layer; and
a molding compound formed over the component, the second die, and the top insulating layer of the PCB.

16. The module of claim 15, wherein a second metal layer of the plurality of metal layers is disposed on a bottom surface of the cavity; wherein the second die is electrically coupled to the second metal layer of the PCB by a first flip-chip mounting between the second die and the second metal layer; wherein a back of the first die is attached to a back of the second die by the first die attach film.

17. The module of claim 15, wherein the second die is electrically coupled to the first metal layer by a second wire-bond; wherein the second die is attached to the cavity by a second die attach film; wherein the second die is mechanically supported by the second die attach film; wherein a back of the first die is attached to a face of the second die by the first die attach film; wherein a back of the second die is attached to the cavity by the second die attach film; wherein at least one end of the second die extends beyond the first die by for receiving the second wire-bond.

18. A module comprising:
a printed circuit board (PCB) including a plurality of metal layers; wherein a first metal layer of the plurality of metal layers is disposed on a top insulating layer of the PCB;
a first die electrically coupled to the PCB by a first flip-chip mounting between the first die and the first metal layer;
a second die electrically coupled to the first die by a second flip-chip mounting between a face of the second die and a face of the first die; wherein at least a portion of the second die is disposed between the first die and the PCB such that the first die is stacked over the second die; wherein a height of the first flip-chip mounting is taller than a height of the second flip-chip mounting;
a component electrically coupled to the first metal layer; and
a molding compound formed over the component, the second die, and the top insulating layer of the PCB.

19. The module of claim 18, wherein the molding compound is formed over the first die.

20. The module of claim 18, wherein the molding compound is formed around the first die; wherein a top surface of the component is disposed below a top surface of the first die; wherein the top surface of the first die is exposed such that the molding compound is not formed over the top surface of the first die for reducing a height of the module; wherein the top surface is exposed by grinding the molding compound.
